(19) United States
(12) Patent Application Publication
(10) Pub. No.: US 2026/0314229 A1
(43) Pub. Date: Oct. 8, 2026

(54) DISPLAY DEVICE, ELECTRONIC DEVICE AND METHOD FOR FABRICATING DISPLAY DEVICE

(71) Applicant: Samsung Display Co., Ltd., Yongin-si (KR)

(72) Inventor: Chun Gi YOU, Yongin-si (KR)

(73) Assignee: Samsung Display Co., Ltd., Yongin-si (KR)

(21) Appl. No.: 19/373,018

(22) Filed: Oct. 29, 2025

(30) Foreign Application Priority Data
Apr. 8, 2025 (KR) 10-2025-0045064

(51) Int. Cl. H10K 59/80; H10K 59/12; H10K 59/122; H10K 102/10

(52) U.S. Cl. CPC H10K 59/80517; H10K 59/1201; H10K 59/122; H10K 59/8723; H10K 59/879; H10K 2102/103

(57) ABSTRACT

The display device includes a substrate, an insulating layer on the substrate, a first electrode and a spacer on the insulating layer, a bank layer on the first electrode and the insulating layer and defining a first opening overlapping the first electrode, a light emitting stack layer on the first electrode, the bank layer, and the spacer, and a second electrode on the light emitting stack layer. The first electrode includes a first conductive layer on the insulating layer and a second conductive layer on the first conductive layer, the spacer includes a first sub-spacer on the insulating layer and a second sub-spacer on the first sub-spacer, the second sub-spacer overlaps the first sub-spacer, in a plan view, an area of the second sub-spacer is more than an area of the first sub-spacer, and the first sub-spacer and the first conductive layer are at a same level.

### CROSS-REFERENCE TO RELATED APPLICATION

This U.S. non-provisional application claims priority under 35 U.S.C. §119 to Korean Patent Application No. 10-2025-0045064 filed on Apr. 8, 2025, in the Korean Intellectual Property Office, the entire contents of which are herein incorporated by reference.

### BACKGROUND

Some example embodiments of the present disclosure relate to a display device, an electronic device, and a method for fabricating a display device configured for reducing or limiting or preventing blackening of an emission area due to damage to a spacer.

An organic light emitting display apparatus includes display elements such as organic light emitting diodes. A luminance of the display elements may be changed by a current.

A head mounted display (HMD) including the organic light emitting display apparatus is an image display device that is worn on a user's head in the form of glasses or a helmet and forms a focus close to user's eyes and in front of the user's eyes. The head mounted display may implement virtual reality (VR) or augmented reality (AR).

The head mounted display magnifies and displays an image displayed by a display device using a plurality of lenses. Therefore, it is beneficial for a display device used in the head mounted display to provide a high-resolution image, for example, an image having a resolution of 3,000 pixels per inch (PPI) or more. An organic light emitting diode on silicon (OLEDoS), which is a relatively smaller organic light emitting display apparatus having a relatively higher resolution, has been used as the display device in the head mounted display. The OLEDoS is a device that displays an image by disposing organic light emitting diodes (OLEDs) on a semiconductor wafer substrate on which complementary metal oxide semiconductors (CMOSs) are disposed.

### SUMMARY

Some example embodiments of the present disclosure provide a display device, an electronic device, and a method for fabricating a display device capable of limiting or reducing or preventing blackening of an emission area due to damage to a spacer.

According to some example embodiments of the present disclosure, a display device includes a substrate, an insulating layer on the substrate, a first electrode and a spacer on the insulating layer, a bank layer on the first electrode and the insulating layer and at least partially defining a first opening overlapping the first electrode, a light emitting stack layer on the first electrode, the bank layer, and the spacer, and a second electrode on the light emitting stack layer. The first electrode includes a first conductive layer on the insulating layer and a second conductive layer on the first conductive layer, the spacer includes a first sub-spacer on the insulating layer and a second sub-spacer on the first sub-spacer, the second sub-spacer at least partially overlaps the first sub-spacer, in a plan view, an area of the second sub-spacer is more than an area of the first sub-spacer, and the first sub-spacer and the first conductive layer are at a same level.

According to some example embodiments of the present disclosure, an electronic device includes: a display device having a resolution of 4,000 pixels per inch (PPI) or more, an optical member external to the display device and configured to adjust a path of light emitted from the display device, and a housing configured to accommodate the display device and the optical member. The display device includes a substrate, an insulating layer on the substrate, a first electrode and a spacer on the insulating layer, a bank layer on the first electrode and the insulating layer and at least partially defining a first opening overlapping the first electrode, a light emitting stack layer on the first electrode, the bank layer, and the spacer, and a second electrode on the light emitting stack layer. The first electrode includes a first conductive layer on the insulating layer and a second conductive layer on the first conductive layer, the spacer includes a first sub-spacer on the insulating layer and a second sub-spacer on the first sub-spacer, the second sub-spacer at least partially overlaps the first sub-spacer, in a plan view, an area of the second sub-spacer is more than an area of the first sub-spacer, and the first sub-spacer and the first conductive layer are at a same level.

According to some example embodiments of the present disclosure, a method for fabricating a display device includes forming an insulating layer on a substrate, forming a first preliminary conductive layer on the insulating layer, the first preliminary conductive layer being connected to a transistor through a contact hole defined in the insulating layer, forming a second sub-spacer on the first preliminary conductive layer, the second sub-spacer not overlapping an emission area, forming a second preliminary conductive layer on the first preliminary conductive layer and the second sub-spacer;
forming a photoresist pattern on the second preliminary conductive layer, the photoresist pattern overlapping the emission area, and patterning the first preliminary conductive layer and the second preliminary conductive layer using the photoresist pattern and the second sub-spacer as masks to form a first conductive layer and a second conductive layer between the photoresist pattern and the insulating layer and form a first sub-spacer between the second sub-spacer and the insulating layer, the second conductive layer being disposed on the first conductive layer, and the first sub-spacer overlapping the second sub-spacer. In a plan view, an area of the second sub-spacer is more than an area of the first sub-spacer, and the first sub-spacer and the first conductive layer are disposed at a same level.

According to some example embodiments, blackening of an emission area due to damage to a spacer may be prevented, or limited or reduced.

For example, according to some example embodiments, a light emitting stack layer may be disconnected or discontinuous on a second sub-spacer by a spacer having an undercut shape. For example, the light emitting stack layer may be disconnected between the second sub-spacer and the emission area. Accordingly, even though an upper surface of the second sub-spacer is damaged by a mask, silicon of a filling layer may not move or propagate to the emission area. Accordingly, the blackening of the emission area due to the damage to the spacer may be prevented, or limited or reduced.

Example embodiments are not limited to the above-described embodiments and other embodiments which are not described herein will become apparent to those skilled in the art from the following description.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view of a display device according to some example embodiments.

FIG. 2 is a plan view of emission areas and spacers disposed in a display area of FIG. 1.

FIG. 3 is a cross-sectional view taken along line I-I′ of FIG. 2.

FIG. 4 is an enlarged view of a fourth insulating layer, a first electrode, a bank layer, and a spacer in area A of FIG. 3.

FIGS. 5, 6, 7, 8, 9, 10, 11, and 12 are cross-sectional views illustrating processes in a method for fabricating the display device according to some example embodiments.

FIG. 13 is a block diagram of an electronic device according to some example embodiments.

FIGS. 14, 15, and 16 are schematic views of electronic devices according to some example embodiments.

FIG. 17 is a perspective view illustrating a head mounted display according to some example embodiments.

### DETAILED DESCRIPTION OF THE EXAMPLE EMBODIMENTS

Example embodiments will now be described hereinafter with reference to the accompanying drawings. Example embodiments may, however, be embodied in different forms and should not be construed as limited to the embodiments set forth herein. Rather, these embodiments are provided so that this disclosure will be thorough and complete, and will fully convey the scope of the disclosure to those skilled in the art.

It will also be understood that when a layer is referred to as being “on” another layer or substrate, it can be directly on the other layer or substrate, or intervening layers may also be present. The same reference numbers indicate the same components throughout the specification. In the attached figures, the thickness of layers and regions is exaggerated for clarity.

Although the terms “first”, “second”, etc. may be used herein to describe various elements, these elements, should not be limited by these terms. These terms may be used to distinguish one element from another element. Thus, a first element discussed below may be termed a second element without departing from teachings of one or more embodiments. The description of an element as a “first” element may not require or imply the presence of a second element or other elements. The terms “first”, “second”, etc. may also be used herein to differentiate different categories or sets of elements. For conciseness, the terms “first”, “second”, etc. may represent “first-category (or first-set)”, “second-category (or second-set)”, etc., respectively.

Features of various embodiments of the present disclosure may be combined partially or totally. As will be clearly appreciated by those skilled in the art, technically various interactions and operations are possible. Some example embodiments can be practiced individually or in combination.

Hereinafter, some example embodiments will be described with reference to the accompanying drawings.

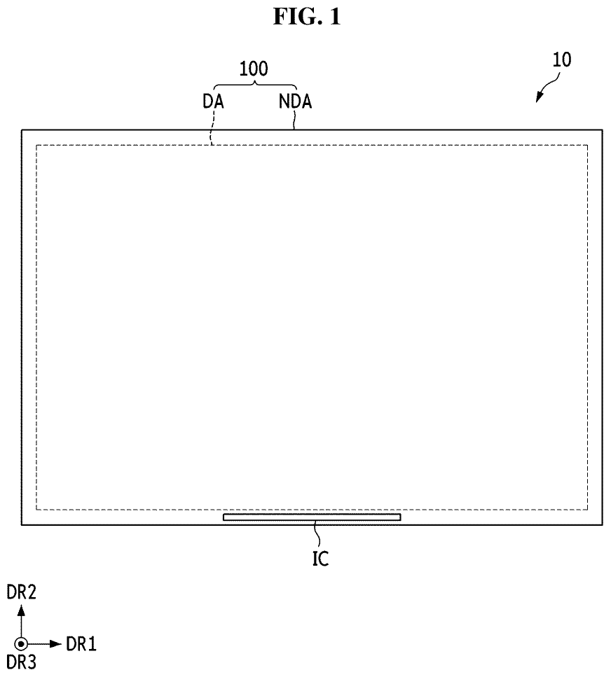

FIG. 1 is a plan view of a display device 10 according to some example embodiments.

The display device 10 is a device that displays a moving image or a still image. The display device 10 may be used in portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). For example, the display device 10 may be used in a display unit of televisions, laptop computers, monitors, billboards, or the Internet of Things (IOTs). Alternatively, the display device 10 may be used in smart watches, watch phones, or head mounted displays (HMDs) 10 for implementing virtual reality and augmented reality.

The display device 10 may have, for example, a resolution of 4,000 pixels per inch (PPI) or more.

The display device 10 may include an active area that implements or displays an image and an inactive area that is disposed outside or around or about the active area and does not implement or display an image. Here, a width (e.g., a maximum width) of the active area may be, for example, 1.5 inches or less. The maximum width may refer to the greatest length in a transverse direction measurable in the active area. For example, when the display device 10 has a rectangular shape, the maximum width described above may correspond to a diagonal length of the display device 10.

The display device 10 may include a display panel 100 and a driving chip IC.

The display device 10 may include a display area DA and a non-display area NDA. For example, the display panel 100 may include a display area DA and a non-display area NDA. The display area DA may be defined as an area that displays a screen, and the non-display area NDA may be defined as an area that does not display a screen or the display of the display device 10. When the display device 10 has a touch function, a touch area, which is an area where touch input is sensed or received or provided, may overlap the display area DA.

The non-display area NDA may be disposed around or surrounding the display area DA. The non-display area NDA may be a bezel area. The non-display areas NDA may surround the display area DA. However, example embodiments of the present disclosure are not limited thereto, and for example, the non-display area NDA may not be disposed in the vicinity of or adjacent to an upper side of the display area DA.

Signal lines or driving circuits for applying signals to the display area DA (or the touch area) may be disposed in the non-display area NDA. In some example embodiments, the driving chip IC may be disposed in the non-display area NA. The driving chip IC may include an integrated circuit that is configured to drive the display panel 100. The integrated circuit may include an integrated circuit for a display and/or an integrated circuit for a touch member.

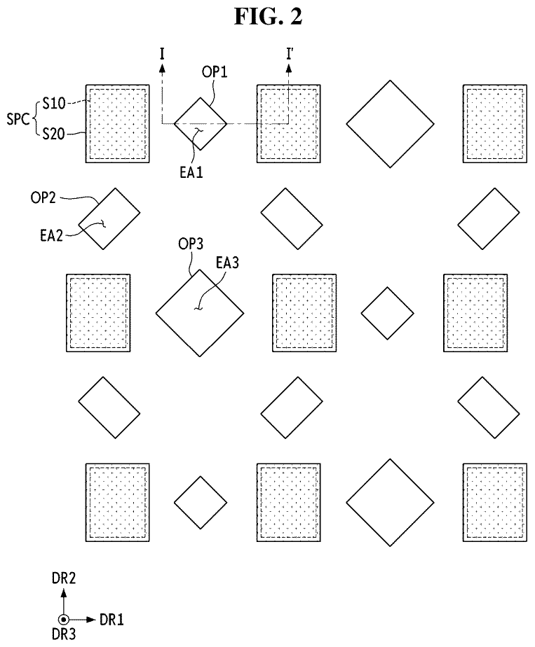

FIG. 2 is a plan view of emission areas and spacers SPC disposed in a display area of FIG. 1.

As illustrated in FIG. 2, a plurality of emission areas (or pixel areas) EA1, EA2, and EA3 and a plurality of spacers SPC may be disposed in the display area DA.

The emission areas EA1, EA2, and EA3 may include first emission areas EA1, second emission areas EA2, and third emission areas EA3 that provide or emit light of different colors. For example, the first emission area EA1 may provide or emit first light, the second emission area EA2 may provide or emit second light, and the third emission area EA3 may provide or emit third light. Here, the first light may be light of a red wavelength band, the second light may be light of a green wavelength band, and the third light may be light of a blue wavelength band. The first emission area EA1, the second emission areas EA2, and the third emission area EA3 adjacent to each other may constitute a unit emission area (or a unit pixel area). For example, the unit emission area may provide a unit image in which the first light from the first emission area EA1, the second light from the second emission area EA2, and the third light from the third emission area EA3 are mixed with each other.

The spacer SPC may serve to support a mask used during a process of fabricating a light emitting stack layer. The spacers SPC may be adjacent to the emission areas EA1, EA2, and EA3. For example, the spacer SPC may be disposed between emission areas adjacent to each other in a first direction DR1. In addition, the spacer SPC may be disposed between the emission areas EA1, EA2, and EA3 adjacent to each other in a second direction DR2.

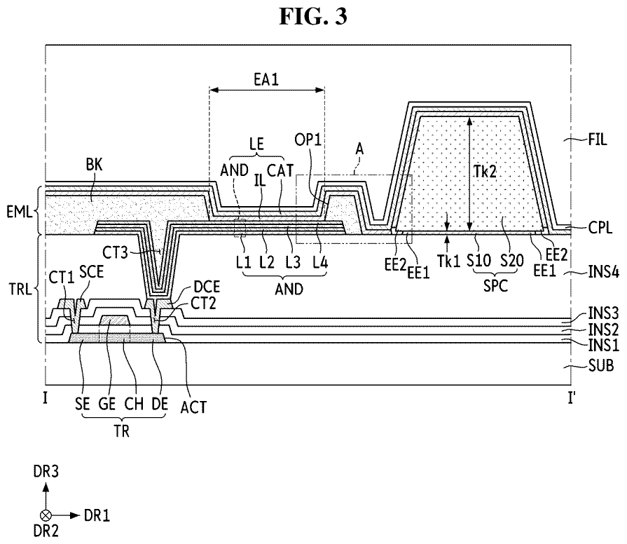

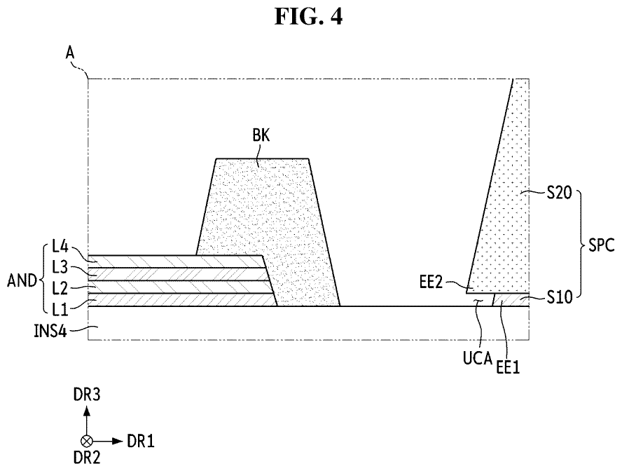

FIG. 3 is a cross-sectional view taken along line I-I′ of FIG. 2, and FIG. 4 is an enlarged view of a fourth insulating layer INS4, a first electrode AND, a bank layer BK, and a spacer SPC in area A of FIG. 3.

Referring to FIG. 3, the display device 10 may include a substrate SUB, a transistor layer TRL disposed on the substrate SUB, a display element layer EML disposed on the transistor layer TRL, a capping layer CPL disposed on the display element layer EML, and a filling layer FIL disposed on the capping layer CPL.

The substrate SUB may be a base substrate or a base member. The substrate SUB may be a flexible substrate that may be bent, folded, and rolled. As an example, the substrate SUB may include a polymer resin such as polyimide (PI), but is not limited thereto. As another example, the substrate SUB may include a glass material or a metal material.

The transistor layer TRL may be disposed on the substrate SUB. The transistor layer TRL may include a plurality of transistors constituting a pixel circuit of each of the emission areas EA1, EA2, and EA3. For example, the transistor layer TRL may include a plurality of insulating layers INS1 to INS4, a transistor TR, a source connection electrode SCE, and a drain connection electrode DCE. Here, the transistor TR may include a channel region CH, a gate electrode GE, a source electrode SE, and a drain electrode DE.

An active layer ACT may be disposed on the substrate SUB. The active layer ACT may include the source electrode, the drain electrode, and the channel region. The active layer ACT may include low temperature polycrystalline silicon (LTPS). Alternatively, the active layer ACT may include an oxide.

A first insulating layer INS1 may be disposed on the active layer ACT. The first insulating layer INS1 may include a silicon compound, metal oxide, or the like. For example, the first insulating layer INS1 may include silicon oxide, silicon nitride, silicon oxynitride, aluminum oxide, tantalum oxide, hafnium oxide, zirconium oxide, titanium oxide, or the like.

The gate electrode GE may be disposed on the first insulating layer INS1. For example, the gate electrode GE may be disposed on the first insulating layer INS1 and may overlap the channel region CH of the active layer ACT. The gate electrode GE may include one or more metals such as molybdenum (Mo), aluminum (Al), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu).

A second insulating layer INS2 may be disposed on the gate electrode GE. The second insulating layer INS2 may include an inorganic insulating material such as silicon oxide, silicon nitride, silicon oxynitride, hafnium oxide, aluminum oxide, titanium oxide, tantalum oxide, or zinc oxide.

A third insulating layer INS3 may be disposed on the second insulating layer INS2. The third insulating layer INS3 may be an interlayer insulating film. The third insulating layer INS3 may include an inorganic insulating material such as silicon oxide, silicon nitride, silicon oxynitride, hafnium oxide, aluminum oxide, titanium oxide, tantalum oxide, or zinc oxide.

The source connection electrode SCE and the drain connection electrode DCE may be disposed on the third insulating layer INS3. The source connection electrode SCE may be connected to the source electrode SE through a first contact hole CT1 penetrating through the third insulating layer INS3, the second insulating layer INS2, and the first insulating layer INS1. The drain connection electrode DCE may be connected to the drain electrode DE through a second contact hole CT2 penetrating through the third insulating layer INS3, the second insulating layer INS2, and the first insulating layer INS1. The source connection electrode SCE may include one or more metals such as aluminum (Al), molybdenum (Mo), platinum (Pt), palladium (Pd), silver (Ag), magnesium (Mg), gold (Au), nickel (Ni), neodymium (Nd), iridium (Ir), chromium (Cr), calcium (Ca), titanium (Ti), tantalum (Ta), tungsten (W), and copper (Cu). The source connection electrode SCE may be a single film or a multilayer film. For example, the source connection electrode SCE may be formed in a stacked structure of Ti/Al/Ti, Mo/Al/Mo, Mo/AlGe/Mo, Ti/Cu, or the like. The drain connection electrode DCE may have the same material and the same structure as the source connection electrode SCE described above.

A fourth insulating layer INS4 may be disposed on the source connection electrode SCE and the drain connection electrode DCE. The fourth insulating layer INS4 may be a planarizing layer for planarizing a flexure (or a step) below the fourth insulating layer INS4. The fourth insulating layer INS4 may include an organic insulating material such as a polyacrylate resin, an epoxy resin, a phenolic resin, a polyamide resin, a polyimide resin, an unsaturated polyester resin, a polyphenyleneether resin, a polyphenylenesulfide resin, or benzocyclobutene (BCB).

The display element layer EML may be disposed on the transistor layer TRL. For example, the display element layer EML may be disposed on the fourth insulating layer INS4. The display element layer EML may include a light emitting element LE, a bank layer BK, and a spacer SPC. The light emitting element LE may include a first electrode AND (e.g., an anode electrode), a light emitting stack layer IL, and a second electrode CAT (e.g., a cathode electrode).

The first electrode AND may be disposed on the fourth insulating layer INS4. For example, the first electrode AND may be disposed on the fourth insulating layer INS4 and may overlap the first emission area EA1. The first electrode AND may be connected to the drain connection electrode DCE through a third contact hole CT3 penetrating through the fourth insulating layer INS4. The first electrode AND may have a structure of a multilayer film. For example, the first electrode AND may include a plurality of conductive layers L1, L2, L3, and L4 stacked along a direction (e.g., a third direction DR3) from a plurality of fourth insulating layers INS4 toward the bank layer BK. According to some example embodiments, the first electrode AND may include a first conductive layer L1, a second conductive layer L2, a third conductive layer L3, and a fourth conductive layer L4.

The first conductive layer L1 may be disposed on the fourth insulating layer INS4. The first electrode AND may be connected to the drain connection electrode DCE through the third contact hole CT3 of the fourth insulating layer INS4. The first conductive layer L1 may be or include transparent conductive oxide (TCO). For example, the first conductive layer L1 may be made of or include a material including indium zinc oxide (IZO).

The second conductive layer L2 may be disposed on the first conductive layer L1. For example, the second conductive layer L2 may be disposed between the first conductive layer L1 and the third conductive layer L3. The second conductive layer L2 may be connected to the first conductive layer L1 and the third conductive layer L3. The second conductive layer L2 may be in contact (or in direct contact) with the first conductive layer L1 and the third conductive layer L3. The second conductive layer L2 may be or include transparent conductive oxide. For example, the first conductive layer L2 may be made of or include a material including indium tin oxide (ITO).

The third conductive layer L3 may be disposed on the second conductive layer L2. For example, the third conductive layer L3 may be disposed between the second conductive layer L2 and the fourth conductive layer L4. The third conductive layer L3 may be connected to the second conductive layer L2 and the fourth conductive layer L4. The third conductive layer L3 may be in contact (or in direct contact) with the second conductive layer L2 and the fourth conductive layer L4. The third conductive layer L3 may include a metal. For example, the third conductive layer L3 may be made of or include a material including silver (Ag).

The fourth conductive layer L4 may be disposed on the third conductive layer L3. For example, the fourth conductive layer L4 may be disposed between the third conductive layer L3 and the light emitting stack layer IL. The fourth conductive layer L4 may be connected to the third conductive layer L3 and the light emitting stack layer IL. The fourth conductive layer L4 may be in contact (or in direct contact) with the third conductive layer L3 and the light emitting stack layer IL. The fourth conductive layer L4 may be or include transparent conductive oxide. For example, the fourth conductive layer L4 may be made of or include a material including ITO. In other words, the fourth conductive layer L4 and the second conductive layer L2 may be made of or include the same material.

In some example embodiments, when the fourth conductive layer L4 and the second conductive layer L2 are made of or include the same material (e.g., ITO), the second conductive layer L2 may be omitted. In such a case, the third conductive layer L3 may be in contact (or in direct contact) with the first conductive layer L1.

The spacer SPC may be disposed on the fourth insulating layer INS4. The spacer SPC may include a first sub-spacer S10 (or a lower sub-spacer SPC) and a second sub-spacer S20 (or an upper sub-spacer SPC) stacked in a thickness direction (e.g., the third direction DR3) of the spacer SPC and may overlap each other in the thickness direction of the spacer SPC.

The first sub-spacer S10 may be disposed on the fourth insulating layer INS4. The first sub-spacer S10 may be made of the same material as at least one of the conductive layers of the first electrode AND. In addition, the first sub-spacer S10 may be disposed at a same level (or coplanar) as at least one of the conductive layers L1 to L4 of the first electrode AND. For example, the first sub-spacer S10 may be made of or include the same material as the second conductive layer L2 of the first electrode AND. According to some example embodiments, each of the first sub-spacer S10 and the second conductive layer L2 may be made of a material including silver. The first sub-spacer S10 and the first electrode AND may be disposed at a same level. In other words, first sub-spacer S10 and the first electrode AND may be coplanar. In some example embodiments, the first sub-spacer S10 and the first conductive layer L1 may be at a same level or coplanar. For example, the first sub-spacer S10 and the first electrode AND may be disposed on the fourth insulating layer INS4.

The second sub-spacer S20 may be disposed on the first sub-spacer S10. In a direction parallel to the substrate SUB (e.g., in the DR1-DR2 plane), an edge EE2 of the second sub-spacer S20 may extend past an edge EE1 of the first sub-spacer S10. In some example embodiments, in a direction parallel to the substrate SUB (e.g., in the DR1-DR2 plane), the edge EE2 of the second sub-spacer S20 may extend toward the first electrode AND (or the bank layer BK) past the edge EE1 of the first sub-spacer S10. In other words, the edge EE2 of the second sub-spacer S20 may overhang the edge EE1 of the first sub-spacer S10. In addition, in some example embodiments, in plan view (e.g., FIG. 2), the edge EE2 of the second sub-spacer S20 may surround the first sub-spacer S10. The edge EE2 of the second sub-spacer S20 does not overlap the edge EE1 of the first sub-spacer S10. In other words, the edge EE2 of the second sub-spacer S20 may be laterally offset (e.g., along the DR1-DR2 plane) from the edge EE1 of the first sub-spacer S10. The edge EE2 of the second sub-spacer S20 thus does not directly overlap the edge EE1 of the first sub-spacer S10. In plan view (e.g., FIG. 2), an area of the second sub-spacer S20 may be greater than an area of the first sub-spacer S10. A thickness of the spacer SPC may be defined as the sum of a thickness Tk1 of the first sub-spacer S10 and a thickness Tk2 of the second sub-spacer S20. The thickness Tk2 of the second sub-spacer S20 may be greater than the thickness Tk1 of the first sub-spacer S10. Here, each of the thickness Tk1 and Tk2 of the first sub-spacer S10 and the second sub-spacer S20 may be defined as a size of the corresponding spacer SPC in the third direction DR3. In some example embodiments, the thickness Tk1 of the first sub-spacer S10 may be same (or substantially same) as a thickness of the first conductive later L1. The second sub-spacer S20 may be made of or include a different material from the first sub-spacer S10. For example, the second sub-spacer S20 may include an organic material. For example, the second sub-spacer S20 may be formed as an organic film made of an acrylic resin, an epoxy resin, a phenolic resin, a polyamide resin, a polyimide resin, or the like. The spacer SPC including the first sub-spacer S10 and the second sub-spacer S20 having the structure described above may have an undercut shape.

The bank layer BK may be disposed on the first electrode AND. For example, the bank layer BK may cover an edge of the first electrode AND. The bank layer BK may define the emission area EA1. For example, the bank layer BK may define the first emission area EA1, the second emission area EA2, and the third emission area EA3. Each of the first emission area EA1, the second emission area EA2, and the third emission area EA3 may be an area where the first electrode AND, the light emitting stack layer IL, and the second electrode CAT are sequentially stacked. For example, each of the first emission area EA1, the second emission area EA2, and the third emission area EA3 may be an area where each light emitting element LE including the first electrode AND, the light emitting stack layer IL, and the second electrode CAT is disposed. Each of the first emission area EA1, the second emission area EA2, and the third emission area EA3 may be partitioned by the bank layer BK. The bank layer BK may have openings OP1, OP2, and OP3 that expose portions of the respective first electrodes AND of the respective emission areas EA1, EA2, and EA3. For example, as illustrated in FIG. 3, the bank layer BK may have a first opening OP1 exposing a portion of the first electrode AND of the first emission area EA1. As illustrated in FIG. 2, the bank layer BK may include a second opening OP2 exposing the first electrode of the second emission area EA2 and a third opening OP3 exposing the first electrode of the third emission area EA3.

The bank layer BK and the spacer SPC may be spaced apart from each other. In other words, the bank layer BK and the spacer SPC may be spaced apart from each other so as not to be in contact with each other. Accordingly, an undercut area UCA (see FIG. 4) (e.g., a space between the edge EE2 of the first sub-spacer S20 and the fourth insulating layer INS4) defined by the spacer SPC may be not be covered by the bank layer BK and may thus be exposed. Accordingly, the light emitting stack layer IL described above may be disconnected in the undercut area UCA of the spacer SPC between the bank layer BK and the spacer SPC.

The bank layer BK may be formed as an organic film made of an acrylic resin, an epoxy resin, a phenolic resin, a polyamide resin, a polyimide resin, or the like. In some example embodiments, the bank layer BK and the second sub-spacer S20 may include different organic materials. For example, the bank layer BK may be made of or include an organic material including a negative photosensitizer, and the second sub-spacer S20 may be made of an organic material including a positive photosensitizer. Conversely, the bank layer BK may be made of an organic material including a positive photosensitizer, and the second sub-spacer S20 may be made of an organic material including a negative photosensitizer.

The light emitting stack layer IL may be disposed on the bank layer BK, the first electrode AND (e.g., on the fourth conductive layer L4), and the spacer SPC (e.g., on the second sub-spacer S20). In this case, the light emitting stack layer IL may be cut on the bank layer BK. For example, the light emitting stack layer IL may be cut or discontinuous between the spacer SPC and the fourth insulating layer INS4. In other words, the light emitting stack layer IL disposed on the bank layer BK and the light emitting stack layer IL disposed on the second sub-spacer S20 may be disconnected from each other. In cross section, the light emitting stack layer IL may be cut along the bank layer BK. Accordingly, the light emitting stack layer IL may be divided into a portion in contact with the first electrode AND in the emission area EA1 and a portion disposed on an area (e.g., the second sub-spacer S20 of the spacer SPC) excluding the emission area EA1. In other words, the light emitting stack layer IL may be cut along the bank layer BK so as to be separated for each of the emission areas EA1, EA2, and EA3.

The light emitting stack layer IL may include a plurality of stack layers that are sequentially stacked along the third direction DR3. For example, the light emitting stack layer IL may have a three-tandem structure including a first stack layer, a second stack layer disposed on the first stack layer, and a third stack layer disposed on the second stack layer. Here, the second stack layer may be disposed between the first stack layer and the third stack layer. Example embodiments of the present disclosure are not limited thereto. For example, the light emitting stack layer IL may also have a two-tandem structure including two stack layers.

In the three-tandem structure, the first stack layer, the second stack layer, and the third stack layer of the light emitting stack layer IL may provide light of different colors (or wavelengths). For example, any one of the first stack layer, the second stack layer, and the third stack layer may provide light of a first color (e.g., green), another of the first stack layer, the second stack layer, and the third stack layer may provide light of a second color (e.g., red), and the other of the first stack layer, the second stack layer, and the third stack layer may provide light of a third color (e.g., blue).

The first stack layer of the light emitting stack layer IL may have a structure in which a first hole transporting layer, a first organic light emitting layer, and a first electron transporting layer are sequentially stacked. The second stack layer of the light emitting stack layer IL may have a structure in which a second hole transporting layer, a second organic light emitting layer, and a second electron transporting layer are sequentially stacked. The third stack layer of the light emitting stack layer IL may have a structure in which a third hole transporting layer, a third organic light emitting layer, and a third electron transporting layer are sequentially stacked. The first organic light emitting layer, the second organic light emitting layer, and the third organic light emitting layer may each provide light of different colors (or wavelengths). For example, any one of the first organic light emitting layer, the second organic light emitting layer, and the third organic light emitting layer may provide light of a first color (e.g., green), another of the first organic light emitting layer, the second organic light emitting layer, and the third organic light emitting layer may provide light of a second color (e.g., red), and the other of the first organic light emitting layer, the second organic light emitting layer, and the third organic light emitting layer may provide light of a third color (e.g., blue).

A first charge generation layer for supplying charges to the second stack layer and supplying electrons to the first stack layer may be disposed between the first stack layer and the second stack layer. The first charge generation layer may include an n-type charge generation layer supplying electrons to the first stack layer and a p-type charge generation layer supplying holes to the second stack layer. The n-type charge generation layer may include a dopant of a metal material.

A second charge generation layer for supplying charges to the third stack layer and supplying electrons to the second stack layer may be disposed between the second stack layer and the third stack layer. The second charge generation layer may include an n-type charge generation layer supplying electrons to the second stack layer and a p-type charge generation layer supplying holes to the third stack layer.

The first stack layer may be disposed on the first electrode AND, the bank layer BK, and the spacer SPC. The first stack layer of the light emitting stack layer IL may be disconnected or discontinuous between the emission areas neighboring to each other by the spacer SPC described above. The second stack layer of the light emitting stack layer IL may be disposed on the first stack layer. The second stack layer of the light emitting stack layer IL may be disconnected or discontinuous between the emission areas neighboring to each other by the spacer SPC described above. The third stack layer of the light emitting stack layer IL may be disposed on the second stack layer. The third stack layer of the light emitting stack layer IL may not be disconnected by the spacer SPC, and may cover the second stack layer.

In the three-tandem structure, the spacer SPC may be a structure for disconnecting the first charge generation layer and the second charge generation layer of the display element layer EML between the emission areas neighboring to each other. In addition, in the two-tandem structure, the spacer SPC may be a structure for disconnecting a charge generation layer disposed between a lower stack layer and an upper stack layer.

The second electrode CAT may be disposed on the light emitting stack layer IL. For example, the second electrode CAT may be disposed on the third stack layer of the light emitting stack layer IL. The second electrode CAT may not be disconnected by the spacer SPC, and may be disposed on the third stack layer of the light emitting stack layer IL. The second electrode CAT may be made of a semi-transmissive conductive material such as magnesium (Mg), silver (Ag), or an alloy of magnesium (Mg) and silver (Ag). Light emission efficiency of each of the first to third emission areas EA1 to EA3 may be increased by a micro cavity.

The capping layer CPL may be disposed on the second electrode CAT. For example, the capping layer CPL may be disposed between the second electrode CAT and the filling layer FIL. The capping layer CPL may include an inorganic film.

The filling layer FIL may be disposed on the capping layer CPL. The filling layer FIL may include silicon.

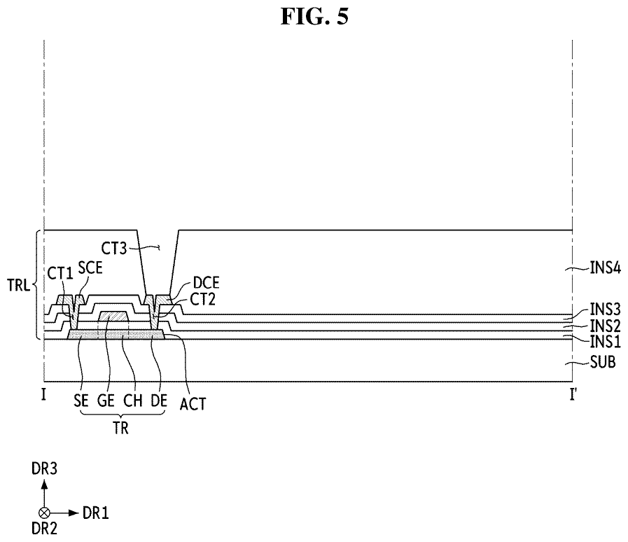

FIGS. 5, 6, 7, 8, 9, 10, 11, and 12 are cross-sectional views for describing processes of a method for fabricating the display device 10 according to some example embodiments. For example, FIGS. 5, 6, 7, 8, 9, 10, 11, and 12 may be cross-sectional views illustrating processes for fabricating the display device 10 described above with reference to FIG. 3.

As illustrated in FIG. 5, the transistor layer TRL may be disposed on the substrate SUB. The transistor layer TRL may include the transistor TR, the plurality of insulating layers INS1 to INS4, the source connection electrode SCE, and the drain connection electrode DCE. Thereafter, the third contact hole CT3 penetrating through the uppermost layer, for example, the fourth insulating layer INS4, of the transistor layer TRL may be formed. The drain connection electrode DCE may be exposed by the third contact hole CT3 of the fourth insulating layer INS4. The drain connection electrode DCE may be connected to the drain electrode DE of the transistor TR through the second contact hole CT2.

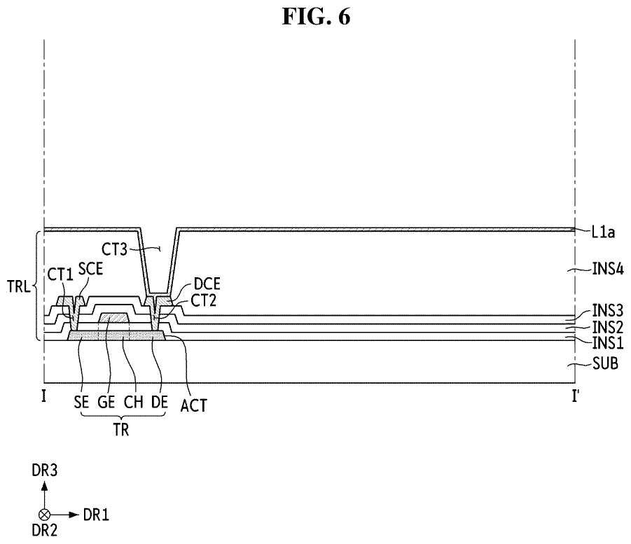

As illustrated in FIG. 6, a first preliminary conductive layer L1a may be disposed on the fourth insulating layer INS4. For example, the first preliminary conductive layer L1a may be formed on an entire surface of the substrate SUB including the fourth insulating layer INS4. Accordingly, the first preliminary conductive layer L1a may be disposed on the fourth insulating layer INS4 and in the third contact hole CT3 of the fourth insulating layer INS4. The first preliminary conductive layer L1a may be in contact (or in direct contact) with the drain connection electrode DCE through the third contact hole CT3. The first preliminary conductive layer L1a may be made of or include a material including, for example, IZO.

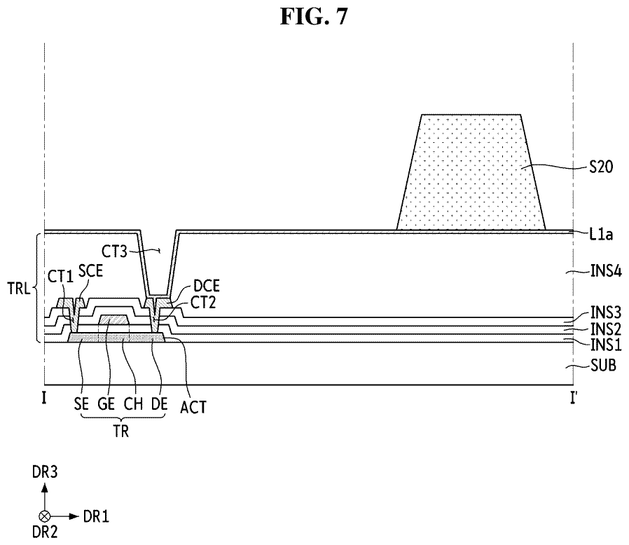

As illustrated in FIG. 7, the second sub-spacer S20 may be formed on the first preliminary conductive layer L1a. For example, the second sub-spacer S20 may be disposed on the first preliminary conductive layer L1a and may not overlap the emission area EA1. The second sub-spacer S20 may be made of or include a material including an organic material.

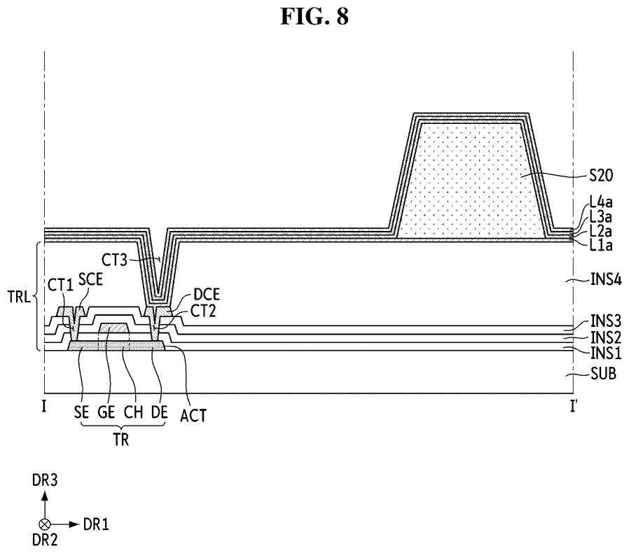

Thereafter, as illustrated in FIG. 8, a second preliminary conductive layer L2a may be formed on the first preliminary conductive layer L1a and the second sub-spacer S20, a third preliminary conductive layer L3a may be formed on the second preliminary conductive layer L2a, and a fourth preliminary conductive layer L4a may be formed on the third preliminary conductive layer L3a. The second preliminary conductive layer L2a may be formed on the entire surface of the substrate SUB including the first preliminary conductive layer L1a and the second sub-spacer S20, the third preliminary conductive layer L3a may be formed on the entire surface of the substrate SUB including the second preliminary conductive layer L2a, and the fourth preliminary conductive layer L4a may be formed on the entire surface of the substrate SUB including the third preliminary conductive layer L3a. Accordingly, the second to fourth preliminary conductive layers L2a to L4a may be disposed on the first preliminary conductive layer L1a and the second sub-spacer S20. The second preliminary conductive layer L2a formed directly on the first preliminary conductive layer L1a may be in contact (or in direct contact) with the first preliminary conductive layer L1a, and the second preliminary conductive layer L2a formed directly on the second sub-spacer S20 may not be in contact with the first preliminary conductive layer L1a. For example, the second preliminary conductive layer L2a formed on the second sub-spacer S20 may overlap the first preliminary conductive layer L1a formed beneath the second sub-spacer S20 in the third direction DR3. The second preliminary conductive layer L2a may be or include a material including ITO, the third preliminary conductive layer L3a may be or include a material including silver (Ag), and the fourth preliminary conductive layer L4a may be or include the same material (e.g., ITO) as the second preliminary conductive layer L2a.

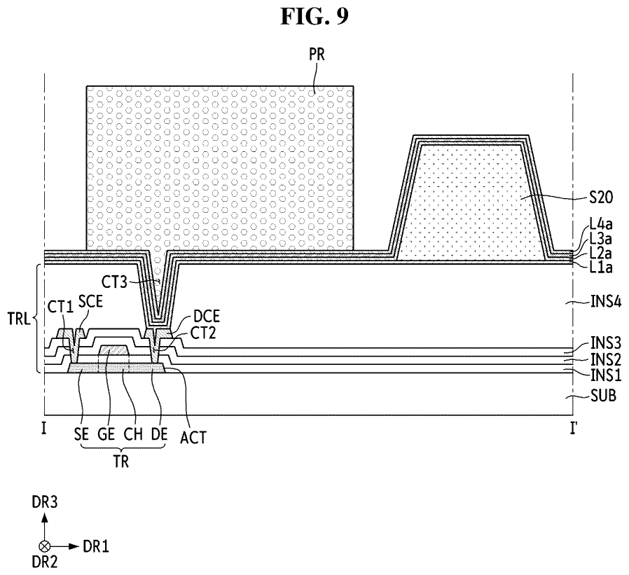

As illustrated in FIG. 9, a photoresist pattern PR may be formed on the fourth preliminary conductive layer L4a so as to overlap the emission area EA1 and the third contact hole CT3. The photoresist pattern PR and the second sub-spacer S20 may include different organic materials. For example, when the second sub-spacer S20 is made of or includes an organic material including a negative photosensitizer, the photoresist pattern PR may be made of or include an organic material including a positive photosensitizer. Conversely, when the second sub-spacer S20 is made of or includes an organic material including a positive photosensitizer, the photoresist pattern PR may be made of an organic material including a negative photosensitizer.

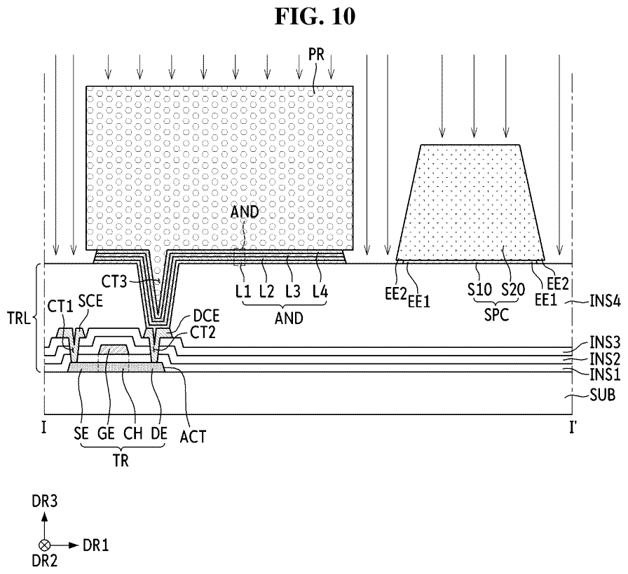

As illustrated in FIG. 10, the first to fourth preliminary conductive layers L1a to L4a may be patterned using the photoresist pattern PR and the second sub-spacer S20 as masks. For example, the first to fourth preliminary conductive layers L1a to L4a may be patterned by etching (e.g., dry etching) the first to fourth preliminary conductive layers L1a to L4a using the photoresist pattern PR and the second sub-spacer S20 as masks. The first to fourth preliminary conductive layers L1a to L4a may be patterned using the photoresist pattern PR as a mask, and the first preliminary conductive layer L1a may be patterned using the second sub-spacer S20 as a mask. As the first to fourth preliminary conductive layers L1a to L4a are patterned, the first electrode AND may be formed between the photoresist pattern PR and the fourth insulating layer INS4, and the first sub-spacer S10 may be formed between the second sub-spacer S20 and the fourth insulating layer INS4. For example, as the first to fourth preliminary conductive layers L1a to L4a are patterned, the first electrode AND may be formed on the fourth insulating layer INS4 so as to overlap the emission area EA1 and the third contact hole CT3, and the first sub-spacer S10 may be formed on the fourth insulating layer INS4 so as to overlap the second sub-spacer S20. As the first to fourth preliminary conductive layers L1a to L4a are patterned, the first electrode AND and the first sub-spacer S10 may be separated from each other.

Due to characteristics (e.g., isotropic etching) of the dry etching, an edge of the first electrode AND may be closer to a virtual center line passing through a center portion of the photoresist pattern PR than an edge of the photoresist pattern PR, and an edge of the first sub-spacer S10 may be closer to a virtual center line passing through a central portion of the second sub-spacer S20 than an edge of the second sub-spacer S20. For example, a structure including the photoresist pattern PR and the first electrode AND may have an undercut shape, and similarly, a structure (e.g., the spacer SPC) including the second sub-spacer S20 and the first sub-spacer S10 may have an undercut shape. As described above, by pattering the first to fourth preliminary conductive layers L1a to L4a using the photoresist pattern PR and the second sub-spacer S20, the first electrode AND including the first to fourth conductive layers L1 to L4 and the spacer SPC including the first sub-spacer S10 and the second sub-spacer S20 may be formed.

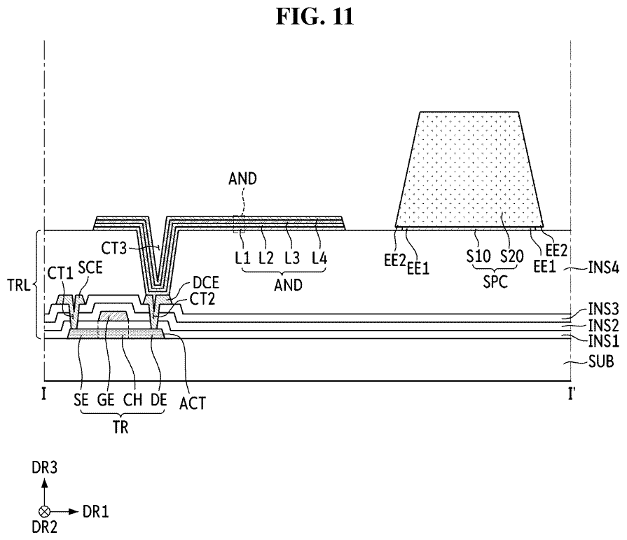

As illustrated in FIG. 11, the photoresist pattern PR may be removed. For example, the photoresist pattern PR may be removed by a stripper.

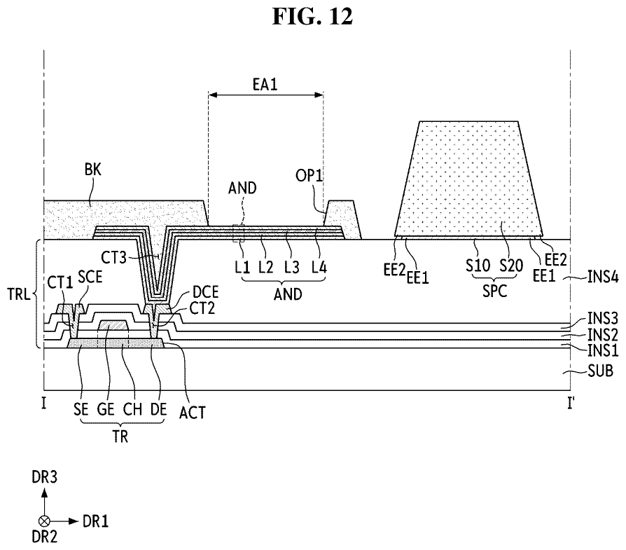

As illustrated in FIG. 12, the bank layer BK may be formed on the first electrode AND. The bank layer BK may include the first opening OP1 defining the first emission area EA1. For example, the bank layer BK may be initially formed on the first electrode AND, and patterning and etching processes may be performed to form the first opening OP1 over the first electrode AND.

The bank layer BK may include an organic material. The bank layer BK and the second sub-spacer S20 may be or include different organic materials. For example, when the second sub-spacer S20 is made of or includes an organic material including a negative photosensitizer, the bank layer BK may be made of or include an organic material including a positive photosensitizer. Conversely, when the second sub-spacer S20 is made of or includes an organic material including a positive photosensitizer, the bank layer BK may be made of or include an organic material including a negative photosensitizer.

As illustrated in FIG. 3, the light emitting stack layer IL may be disposed on the bank layer BK, the first electrode AND (e.g., on the fourth conductive layer L4), and the spacer SPC (e.g., on the second sub-spacer S20). The light emitting stack layer IL may be disconnected on the second sub-spacer S20 by the spacer SPC having the undercut shape. As illustrated in FIG. 3, the second electrode CAT may be formed on the light emitting stack layer IL, the capping layer CPL may be formed on the second electrode CAT, and the filling layer FIL may be formed on the capping layer CPL. The second electrode CAT may or may not be cut in an area overlapping the spacer SPC.

According to some example embodiments, the spacer SPC may serve as a separator for disconnecting the light emitting stack layer IL, and may also serve as a support layer for supporting a mask (e.g., a mask for forming the light emitting stack layer IL).

In a process of forming the light emitting stack layer IL, the mask described above may be in contact with the spacer SPC (e.g., the second sub-spacer S20), and an upper surface of the second sub-spacer S20 may be damaged by such contact. For example, the surface of the second sub-spacer S20 in contact with the mask may have an irregular rugged shape. Accordingly, after the mask is removed, a crack may occur in the light emitting stack layer IL that is on the upper surface of the second sub-spacer S20 and in contact (e.g., direct contact) with the upper surface of the second sub-spacer S20. Such a crack may propagate to the second electrode CAT and the capping layer CPL disposed on the light emitting stack layer IL. The silicon of the filling layer FIL may permeate or seep into the light emitting stack layer IL through the crack. For example, the silicon of the filling layer FIL may permeate into the light emitting stack layer IL (e.g., the light emitting stack layer IL damaged through the crack) disposed on the second sub-spacer S20. The silicon that has permeated into the light emitting stack layer IL may move along the light emitting stack layer IL to move to the light emitting stack layer IL of the emission area (e.g., EA1). The silicon may impede the movement of electrons and holes in the light emitting stack layer IL of the emission area EA1, such that light may not be emitted from the emission area EA1. In other words, the emission area EA1 may be blackened by the silicon of the filling layer FIL. However, according to some example embodiments, the light emitting stack layer IL may be disconnected or interrupted on the second sub-spacer S20 by the spacer SPC having the undercut shape. For example, the light emitting stack layer IL may be disconnected or discontinuous between the second sub-spacer S20 and the emission area EA1 due to gap or space formed in the light emitting stack layer IL due to the spacer SPC having the undercut shape. Accordingly, even though the upper surface of the second sub-spacer S20 may be damaged by the mask, a path for the silicon to reach the light emitting stack layer IL of the emission area (e.g., EA1) is broken and, as a result, the silicon of the filling layer FIL may not move or relocate to the emission area EA1. As a result, the blackening of the emission area EA1 due to the damage to the spacer SPC may be prevented, limited, or reduced.

The display device 10, according to some example embodiments, may be used in various electronic devices. An electronic device, according to some example embodiments, includes the display device 10 described above, and may further include modules or devices having other additional functions in addition to the display device 10.

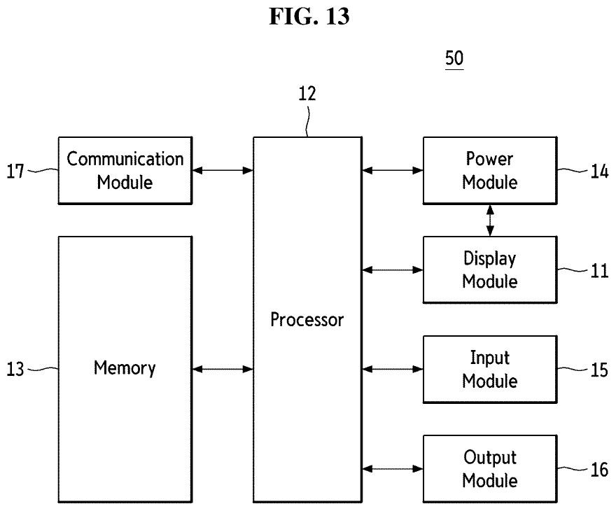

FIG. 13 is a block diagram of an electronic device 50 according to some example embodiments. Referring to FIG. 13, the electronic device 50 may include a display module 11, a processor 12, a memory 13, and a power module 14. The electronic device 50 may further include an input module 15, a non-image output module (or an output module) 16, and/or a communication module 17.

The electronic device 50 may output various information in the form of an image through the display module 11. When the processor 12 executes an application stored in the memory 13, image information provided by the application may be provided to a user through the display module 11. The power module 14 may include a power supply module such as a power adapter or a battery device and a power conversion module converting power supplied by the power supply module to generate power required for an operation of the electronic device 50. The input module 15 may provide input information to the processor 12 and/or the display module 11. The non-image output module 16 may receive information other than an image received from the processor 12, such as sound information, haptic information, and light emitting information, and provide the received information to the user. The communication module 17 is a module in charge of transmitting and receiving information between the electronic device 50 and an external device, and may include a receiving unit and a transmitting unit.

At least one of the respective components of the above-described electronic device 50 may be included in the display device according to the above-described embodiments. In addition, some of individual modules functionally included in one module may be included in the display device, and the others of the individual modules may be provided separately from the display device. For example, the display device may include the display module 11, and the processor 12, the memory 13, and the power module 14 may be provided in the form of other devices within the electronic device 50 rather than the display device.

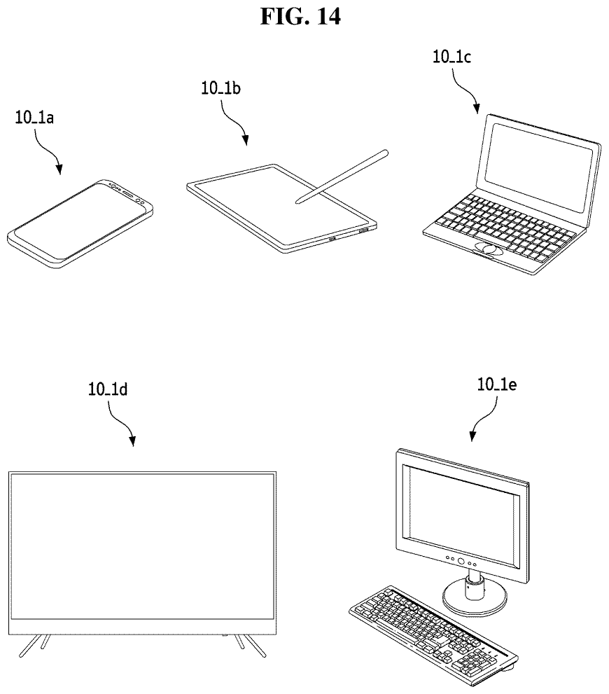

FIGS. 14 to 16 are schematic views of electronic devices according to various embodiments. FIGS. 14 to 16 illustrate examples of various electronic devices that may include the display device 10 according to some example embodiments discussed above.

FIG. 14 illustrates a smartphone 10_1a, a tablet personal computer (PC) 10_1b, a laptop computer 10_1c, a television (TV) 10_1d, and a monitor 10_1e for a desktop computer as examples of the electronic devices.

The smartphone 10_1a may include an input module such as a touch sensor and a communication module in addition to the display module 11. The smartphone 10_1a may process information received through the communication module or other input modules and display the processed information through the display module of the display device.

Each of the tablet PC 10_1b, the laptop computer 10_1c, the TV 10_1d, and the monitor 10_1e for a desktop computer may include a display module and an input module, similar to the smartphone 10_1a, and may further include a communication module in some example embodiments.

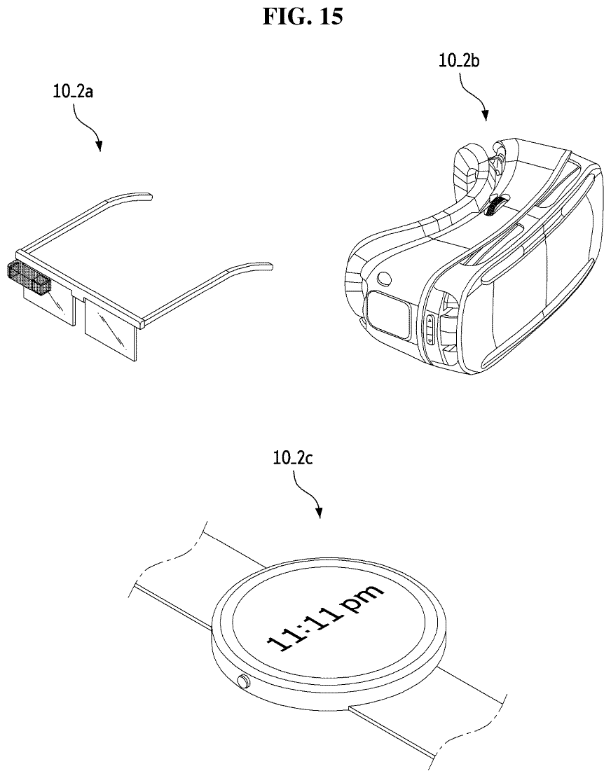

FIG. 15 illustrates wearable electronic devices that incorporates therein an electronic device including a display module. The wearable electronic device may be a smart glasses 10_2a, a head mounted display 10_2b, a smart watch 10_2c, or the like.

Each of the smart glasses 10_2a and the head mounted display 10_2b may include a display module emitting a display image and a reflector reflecting the emitted display image and providing the emitted display image to user's eyes, and accordingly, may provide a virtual reality screen or an augmented reality screen to the user.

The smart watch 10_2c may include a biometric sensor as an input device, and may provide biometric information recognized through the biometric sensor to the user through the display module.

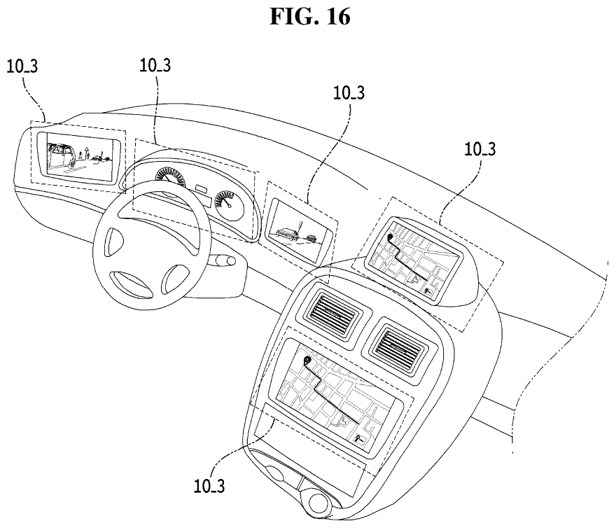

FIG. 16 illustrates part of a vehicle (e.g., an automobile) that incorporates therein an electronic device including a display module. For example, an electronic device 10_3 may be used in an instrument board, a center fascia, or the like, of the vehicle or used in a center information display (CID) located on a dashboard of the vehicle, a room mirror display substituting for a side-view mirror, or the like.

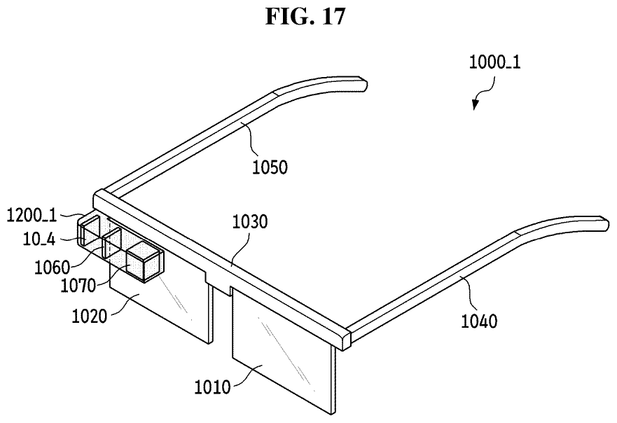

FIG. 17 is a perspective view illustrating a head mounted display device 1000_1 according to some example embodiments. For example, FIG. 17 illustrates the smart glasses 10_2a of FIG. 15.

Referring to FIG. 17, a head mounted display device 1000_1 may be a glasses-type display device in which a display device housing portion 1200_1 (or simply, a housing 1200_1) is implemented (or otherwise designed) to have a light weight and a relatively smaller size. The head mounted display device 1000_1 according to some example embodiments may include a display device 10_4, a left eye lens 1010, a right eye lens 1020, a support frame 1030, glasses frame legs 1040 and 1050, an optical member 1060 (e.g., a lens), an optical path conversion member 1070 (e.g., a mirror), and a display device housing portion 1200_1. In some example embodiments, the display device 10_4 may be or include the display device 10, according to some example embodiments discussed above.

The display device housing portion 1200_1 may be sized and shaped (or otherwise configured) to include or accommodate the display device 10_4, the optical member 1060, and the optical path conversion member 1070. The optical member 1060 may magnify an image displayed on the display device 10_4, the optical path conversion member 1070 may adjust the optical path of the light emitted from the display device 10_4, and the light may be provided to a user's right eye through the right eye lens 1020. A user may view an augmented reality image in which a virtual image displayed on the display device 10_4 through the user's right eye and a real image seen through the right eye lens 1020 combine with each other.

It is illustrated in FIG. 17 that the display device housing portion 1200_1 is disposed on a right end (or side) of the support frame 1030, but example embodiments of the present disclosure are not limited thereto. For example, the display device housing portion 1200_1 may be disposed on a left end (or side) of the support frame 1030, and in this case, an image of the display device 10_4 may be provided to a user's left eye. Alternatively, the display device housing portions 1200_1 may be disposed on both the left and right ends (or sides) of the support frame 1030, and in this case, the user may view an image displayed on the display device 10_4 through both the user's left and right eyes.

As described herein, any devices, systems, modules, portions, units, controllers, circuits, and/or portions thereof according to any of the example embodiments, and/or any portions thereof (including, without limitation, the display module 11, the processor 12, the memory 13, the power module 14, the input module 15, the non-image output module (or an output module) 16, the communication module 17, the smartphone 10_1a, the tablet personal computer (PC) 10_1b, the laptop computer 10_1c, the television (TV) 10_1d, the monitor 10_1e, the smart glasses 10_2a, the head mounted display 10_2b, the smart watch 10_2c, the electronic device 10_3, any portion thereof, or the like) may include, may be included in, and/or may be implemented by one or more instances of processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a graphics processing unit (GPU), an application processor (AP), a digital signal processor (DSP), a microcomputer, a field programmable gate array (FPGA), and programmable logic unit, a microprocessor, application-specific integrated circuit (ASIC), a neural network processing unit (NPU), an Electronic Control Unit (ECU), an Image Signal Processor (ISP), and the like. In some example embodiments, the processing circuitry may include a non-transitory computer readable storage device (e.g., a memory), for example a solid state drive (SSD), storing a program of instructions, and a processor (e.g., CPU) configured to execute the program of instructions to implement the functionality and/or methods performed by some or all of any devices, systems, modules, portions, units, controllers, circuits, and/or portions thereof according to any of the example embodiments.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

While several embodiments have been provided in the present disclosure, it should be understood that the disclosed systems and methods might be embodied in many other specific forms without departing from the spirit or scope of the present disclosure. The present examples are to be considered as illustrative and not restrictive, and the intention is not to be limited to the details given herein. For example, the various elements or components may be combined or integrated in another system or certain features may be omitted, or not implemented.

What is claimed is:

1. A display device comprising:
a substrate;
an insulating layer on the substrate;
a first electrode and a spacer on the insulating layer;
a bank layer on the first electrode and the insulating layer and at least partially defining a first opening overlapping the first electrode;
a light emitting stack layer on the first electrode, the bank layer, and the spacer; and
a second electrode on the light emitting stack layer,
wherein the first electrode includes a first conductive layer on the insulating layer and a second conductive layer on the first conductive layer,
the spacer includes a first sub-spacer on the insulating layer and a second sub-spacer on the first sub-spacer,
the second sub-spacer at least partially overlaps the first sub-spacer,
in a plan view, an area of the second sub-spacer is more than an area of the first sub-spacer, and
the first sub-spacer and the first conductive layer are at a same level.

2. The display device of claim 1, wherein the first sub-spacer and the first conductive layer include a same material.

3. The display device of claim 2, wherein the first sub-spacer and the first conductive layer each include a transparent conductive oxide.

4. The display device of claim 1, wherein the first sub-spacer and the first conductive layer each include indium zinc oxide (IZO).

5. The display device of claim 1, wherein the first sub-spacer and the second sub-spacer include different materials.

6. The display device of claim 1, wherein in a direction parallel to the substrate, an edge of the second sub-spacer extends past an edge of the first sub-spacer.

7. The display device of claim 1, wherein the bank layer and the spacer are spaced apart from each other.

8. The display device of claim 1, wherein the first electrode further includes:
a third conductive layer on the second conductive layer; and
a fourth conductive layer on the third conductive layer.

9. The display device of claim 8, wherein the first conductive layer includes IZO,
the second conductive layer and the fourth conductive layer each include indium tin oxide (ITO), and
the third conductive layer includes silver.

10. The display device of claim 1, wherein, in the plan view, an edge of the second sub-spacer surrounds the first sub-spacer.

11. The display device of claim 1, wherein a thickness of the second sub-spacer is more than a thickness of the first sub-spacer.

12. The display device of claim 1, wherein the light emitting stack layer on the bank layer and the light emitting stack layer on the second sub-spacer are disconnected from each other.

13. An electronic device comprising:
a display device having a resolution of 4,000 pixels per inch (PPI) or more;
an optical member external to the display device and configured to adjust a path of light emitted from the display device; and
a housing configured to accommodate the display device and the optical member,
wherein the display device includes,
a substrate;
an insulating layer on the substrate;
a first electrode and a spacer on the insulating layer;
a bank layer on the first electrode and the insulating layer and at least partially defining a first opening overlapping the first electrode;
a light emitting stack layer on the first electrode, the bank layer, and the spacer; and
a second electrode on the light emitting stack layer, wherein
the first electrode includes a first conductive layer on the insulating layer and a second conductive layer on the first conductive layer,
the spacer includes a first sub-spacer on the insulating layer and a second sub-spacer on the first sub-spacer,
the second sub-spacer at least partially overlaps the first sub-spacer,
in a plan view, an area of the second sub-spacer is more than an area of the first sub-spacer, and
the first sub-spacer and the first conductive layer are at a same level.

14. The electronic device of claim 13, wherein the display device includes an active area that is configured to implement an image and an inactive area that is outside the active area and is not configured to implement an image, and
a maximum width of the active area is 1.5 inches or less

15. The electronic device of claim 13, wherein the optical member includes at least one of a lens and a mirror.

16. The electronic device of claim 13, wherein the electronic device is a wearable device including a head mounted display, a smart glasses, or a smart watch.

17. A method for fabricating a display device, comprising:
forming an insulating layer on a substrate;
forming a first preliminary conductive layer on the insulating layer, the first preliminary conductive layer being connected to a transistor through a contact hole defined in the insulating layer;
forming a second sub-spacer on the first preliminary conductive layer, the second sub-spacer not overlapping an emission area;
forming a second preliminary conductive layer on the first preliminary conductive layer and the second sub-spacer;
forming a photoresist pattern on the second preliminary conductive layer, the photoresist pattern overlapping the emission area; and
patterning the first preliminary conductive layer and the second preliminary conductive layer using the photoresist pattern and the second sub-spacer as masks to form a first conductive layer and a second conductive layer between the photoresist pattern and the insulating layer and form a first sub-spacer between the second sub-spacer and the insulating layer, the second conductive layer being disposed on the first conductive layer, and the first sub-spacer overlapping the second sub-spacer,
wherein in a plan view, an area of the second sub-spacer is more than an area of the first sub-spacer, and
the first sub-spacer and the first conductive layer are disposed at a same level.

18. The method of claim 17, wherein the first sub-spacer and the first conductive layer include a same material.

19. The method of claim 17, wherein in a direction parallel to the substrate, an edge of the second sub-spacer extends past an edge of the first sub-spacer.

20. The method of claim 17, wherein a first electrode comprises the first conductive layer and the second conductive layer, and the method further comprises:
removing the photoresist pattern; and
forming a bank layer on the second conductive layer such that the first electrode and a spacer including the first sub-spacer and the second sub-spacer are spaced apart from each other.
